(19) United States
(12) Patent Application Publication
(10) Pub. No.: US 2008/0231176 A1
(43) Pub. Date: Sep. 25, 2008

(54) LIGHT EMITTING DEVICE

(76) Inventors: Jongmoo Lee, Seoul (KR); Myungseop Kim, Seoul (KR); Jeongdae Seo, Seoul (KR)

Correspondence Address: KED & ASSOCIATES, LLP, P.O. Box 221200, Chantilly, VA, 20153-1200, US

(21) Appl. No.: 12/015,058

(22) Filed: Jan. 16, 2008

(30) Foreign Application Priority Data
Mar. 21, 2007 (KR) 10-2007-0027867

(51) Int. Cl. H01L 27/28

(52) U.S. Cl. 313/504

(57) ABSTRACT

A light emitting device is disclosed. The light emitting device includes a first substrate, a light emitting unit that is positioned on the first substrate and includes a first electrode, a light emitting layer, and a second electrode, and an organic phosphor layer positioned at a location corresponding to the light emitting layer.

This application claims the benefit of Korean Patent Application No. 10-2007-0027867 filed on Mar. 21, 2007, which is hereby incorporated by reference.

### BACKGROUND

1. Field

An exemplary embodiment relates to a light emitting device.

2. Description of the Related Art

A light emitting device has a self-emitting structure in which a pixel includes a light emitting layer interposed between two electrodes. The light emitting device forms an exciton by combining electrons and holes received from the two electrodes inside the light emitting layer, and emits light by an energy difference generated when an energy level of the exciton changes from an excited level to a ground level after the elapse of a predetermined time.

In case that the light emitting display is applied to a light source, the light emitting display needed to have a structure capable of emitting white light. In particular, in case that the light emitting display is applied to a backlight unit, the light emitting display needed to have a structure capable of emitting white light by combining three frequencies of red, green and blue light so as to achieve full color representation on a display panel.

### SUMMARY

An exemplary embodiment provides a light emitting device capable of emitting white-based light applicable to a light source and a backlight unit.

In one aspect, a light emitting device comprises a first substrate, a light emitting unit on the first substrate, the light emitting unit including a first electrode, a light emitting layer, and a second electrode, and an organic phosphor layer positioned at a location corresponding to the light emitting layer.

In another aspect, a light emitting device comprises a first substrate, an organic phosphor layer on the first substrate, an insulating layer covering the organic phosphor layer, and a light emitting unit positioned on the insulating layer at a location corresponding to the organic phosphor layer.

### BRIEF DESCRIPTION OF THE DRAWINGS

The accompanying drawings, which are included to provide a further understanding of the invention and are incorporated on and constitute a part of this specification, illustrate embodiments of the invention and together with the description serve to explain the principles of the invention. In the drawings:

FIG. 1 is a cross-sectional view showing a first implementation of a structure of a light emitting device according to an exemplary embodiment;

FIG. 2 is a cross-sectional view of a pixel of the light emitting device according to the exemplary embodiment;

FIG. 3 is a cross-sectional view showing a second implementation of a structure of the light emitting device according to the exemplary embodiment;

FIG. 4 is a cross-sectional view showing a third implementation of a structure of the light emitting device according to the exemplary embodiment; and structure of the light emitting device according to the exemplary embodiment.

### DETAILED DESCRIPTION

Reference will now be made in detail embodiments of the invention examples of which are illustrated in the accompanying drawings.

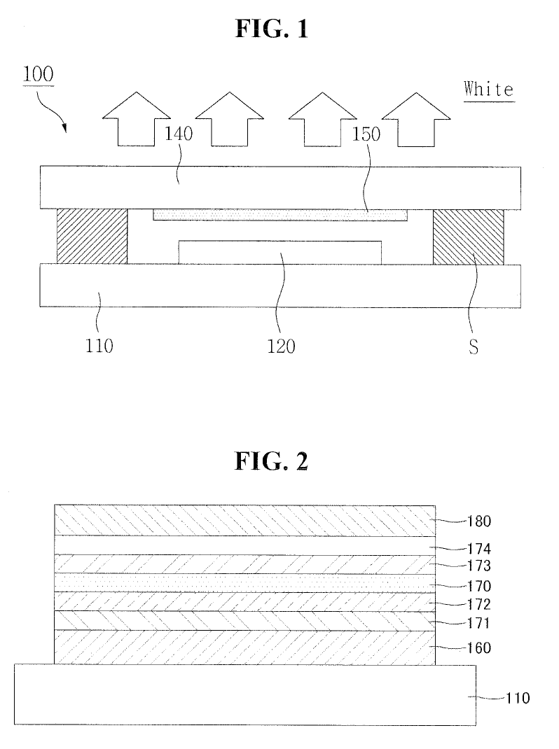

FIG. 1 is a cross-sectional view showing a first implementation of a structure of a light emitting device according to an exemplary embodiment.

As shown in FIG. 1, a light emitting device 100 includes a first substrate 110 and a pixel 120 on the first substrate 110. The pixel 120 may include a light emitting layer interposed between a first electrode and a second electrode. The pixel 120 may additionally include a thin film transistor depending on a driving manner, and the thin film transistor may be electrically connected to the first electrode.

A protective unit 140 is positioned on the first substrate 110. The protective unit 140 may be attached to the first substrate 110 using a sealant (S). The protective unit 140 may be a glass or a cap having light transmission properties depending on light emitting characteristics of the light emitting device 100.

An organic phosphor layer 150 may be positioned on the protective unit 140 at a location corresponding to the pixel 120 (i.e., at the opposite side of the pixel 120). The organic phosphor layer 150 may be formed of a low molecular weight organic material and a high molecular weight organic material.

In case that the organic phosphor layer 150 is formed of a low molecular weight organic material, the organic phosphor layer 150 may be formed using a thermal evaporation method. In case that the organic phosphor layer 150 is formed of a high molecular weight organic material, the organic phosphor layer 150 may be formed using a spin coating method.

The organic phosphor layer 150 may include any one selected from the group consisting of anthracene-based compound, pyrene-based compound, perylene-based compound, and coumarin-based compound.

Light produced by the organic phosphor layer 150 may be represented by X and Y coordinates based on CIE color system. The X coordinate may lie substantially in a range between 0.300 and 0.700, and the Y coordinate may lie substantially in a range between 0.200 and 0.600. The organic phosphor layer 150 may substantially have a thickness of 0.1 μm to 100 μm so as to efficiently perform a color change operation.

In the light emitting device 100, the light emitting layer of the pixel 120 may produce blue-based light, and the organic phosphor layer 150 may produce yellow-based light or orange-based light. Hence, the blue-based light produced by the pixel 120 passes through the organic phosphor layer 150 and then is incident on the protective unit 140, and thus can be changed into white-based light.

Further, in the light emitting device 100, the light emitting layer of the pixel 120 may produce blue-based light. Although it is not shown, the organic phosphor layer 150 may include a first organic phosphor layer emitting red-based light and a second organic phosphor layer emitting green-based light. Hence, the blue-based light produced by the pixel 120 passes through the organic phosphor layer 150 and then is incident on the protective unit 140, and thus can be changed into white-based light.

FIG. 2 is a cross-sectional view of a pixel of the light emitting device according to the exemplary embodiment.

As shown in FIG. 2, in the light emitting device according to the exemplary embodiment, the pixel 120 may include a first electrode 160 on the substrate 110, a hole injection layer 171 on the first electrode 160, a hole transport layer 172, a light emitting layer 170, an electron transport layer 173, an electron injection layer 174, and a second electrode 180 on the electron injection layer 174.

The first electrode 160 may be an anode electrode. In case that the light may be formed of a transparent material such as indium-tin-oxide (ITO), indium-zinc-oxide (IZO), or zinc oxide (ZnO). In case that the light emitting device has a top emission structure, the first electrode 160 may include a layer formed of one of ITO, IZO or ZnO, and a reflective layer formed of one of aluminum (Al), silver (Ag) or nickel (Ni) under the layer. Further, the first electrode 160 may have a multi-layered structure in which the reflective layer is positioned between two layers formed of one of ITO, IZO or ZnO.

The second electrode 180 may be a cathode electrode, and may be formed of magnesium (Mg), calcium (Ca), Al and Ag having a low work function or a combination thereof. In case that the light emitting device has a top emission or dual emission structure, the second electrode 180 may be thin enough to transmit light. In case that the light emitting device has a bottom emission structure, the second electrode 180 may be thick enough to reflect light.

The hole injection layer 171 may function to facilitate the injection of holes from the first electrode 160 to the light emitting layer 170. The hole injection layer 171 may be formed of at least one selected from the group consisting of copper phthalocyanine (CuPc), PEDOT(poly(3,4)-ethylenedioxythiophene), polyaniline (PANI) and NPD(N,N-dinaphthyl-N,N′-diphenyl benzidine), but is not limited thereto. The hole injection layer 171 may be formed using an evaporation method or a spin coating method.

The hole transport layer 172 functions to smoothly transport holes. The hole transport layer 172 may be formed from at least one selected from the group consisting of NPD(N,N-dinaphthyl-N,N′-diphenyl benzidine), TPD(N,N′-bis-(3-methylphenyl)-N,N′-bis-(phenyl)-benzidine, s-TAD and MTDATA(4,4′,4″-Tris(N-3-methylphenyl-N-phenyl-amino)-triphenylamine), but is not limited thereto. The hole transport layer 172 may be formed using an evaporation method or a spin coating method.

Although the light emitting layer 170 may produce blue-based light in the exemplary embodiment, it is not limited thereto. The light emitting layer 170 may be formed of a material capable of emitting red, green, blue and white light, for example, a phosphorescence material or a fluorescence material.

In case that the light emitting layer 170 produces red light, the light emitting layer 170 includes a host material including carbazole biphenyl (CBP) or N,N-dicarbazolyl-3,5-benzene (mCP). Further, the light emitting layer 170 may be formed of a phosphorescence material including a dopant material including any one selected from the group consisting of PIQIr(acac)(bis(1-phenylisoquinoline)acetylacetonate iridium), PQIr(acac)(bis(1-phenylquinoline)acetylacetonate iridium), PQIr(tris(1-phenylquinoline)iridium) and PtOEP(octaethylporphyrin platinum) or a fluorescence material including PBD:Eu(DBM)3(Phen) or Perylene, but is not limited thereto.

In case that the light emitting layer 170 produces green light, the light emitting layer 170 includes a host material including CBP or mCP. Further, the light emitting layer 170 may be formed of a phosphorescence material including a dopant material including Ir(ppy)3(fac tris(2-phenylpyridine)iridium) or a fluorescence material including Alq3(tris(8-hydroxyquinolino)aluminum), but is not limited thereto.

In case that the light emitting layer 170 produces blue light, the light emitting layer 170 includes a host material including CBP or mCP. Further, the light emitting layer 170 may be formed of a phosphorescence material including a dopant material including (4,6-F2 ppy)2Irpic or a fluorescence material including any one selected from the group consisting of spiro-DPVBi, spiro-6P, distyryl-benzene (DSB), distyryl-arylene (DSA), PFO-based polymers, PPV-based polymers and a combination thereof, but is not limited thereto.

The electron transport layer 173 functions to facilitate the transportation of electrons. The electron transport layer 173 may be formed of at least one selected from the group consisting of Alq3(tris(8-hydroxyquinolino)aluminum, PBD, TAZ, spiro-PBD, BAlq, and SAlq, but is not limited thereto. The electron transport layer 173 may be formed using an evaporation method or a spin coating method.

The electron transport layer 173 can also function to prevent holes, which are injected from the first electrode 160 and then pass through the light emitting layer 170, from moving to the second electrode 180. In other words, the electron transport layer 173 serves as a hole stop layer, which facilitates the coupling of holes and electrons in the light emitting layer 170.

The electron injection layer 174 functions to facilitate the injection of electrons. The electron injection layer 174 may be formed of Alq3(tris(8-hydroxyquinolino)aluminum), PBD, TAZ, spiro-PBD, BAlq or SAlq, but is not limited thereto. The electron injection layer 174 may be formed of an organic material and an inorganic material forming the electron injection layer 174 through a vacuum evaporation method.

The hole injection layer 171 or the electron injection layer 174 may further include an inorganic material. The inorganic material may further include a metal compound. The metal compound may include alkali metal or alkaline earth metal. The metal compound including the alkali metal or the alkaline earth metal may include at least one selected from the group consisting of LiQ, LiF, NaF, KF, RbF, CsF, FrF, BeF₂, Mg F₂, Ca F₂, Sr F₂, Ba F₂, and Ra F₂, but is not limited thereto.

Thus, the inorganic material inside the electron injection layer 174 facilitates hopping of electrons injected from the second electrode 180 to the light emitting layer 170, so that holes and electrons injected into the light emitting layer 170 are balanced. Accordingly, the light emission efficiency can be improved.

Further, the inorganic material inside the hole injection layer 171 reduces the mobility of holes injected from the first electrode 160 to the light emitting layer 170, so that holes and electrons injected into the light emitting layer 170 are balanced. Accordingly, the light emission efficiency can be improved.

At least one of the electron injection layer 174, the electron transport layer 173, the hole transport layer 172, the hole injection layer 171 may be omitted.

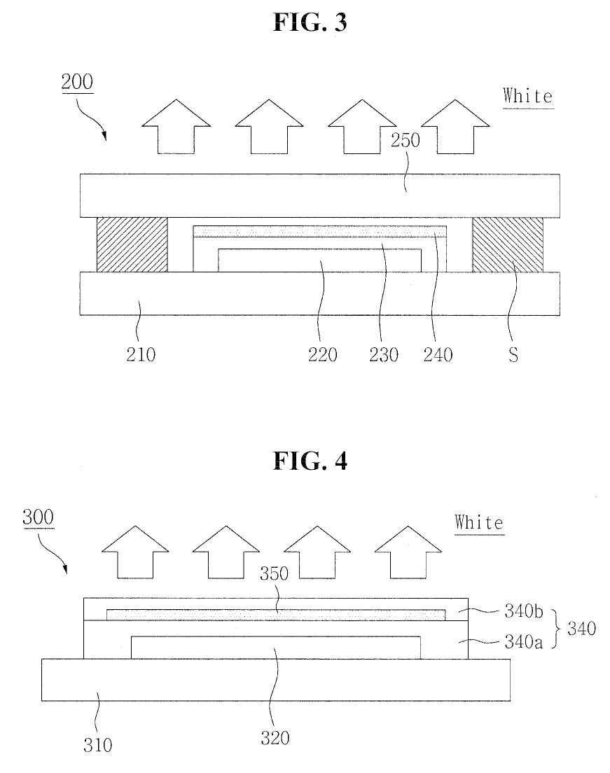

FIG. 3 is a cross-sectional view showing a second implementation of a structure of the light emitting device according to the exemplary embodiment.

As shown in FIG. 3, a light emitting device 200 includes a first substrate 210 and a pixel 220 on the first substrate 210. The pixel 220 may include a light emitting layer interposed between a first electrode and a second electrode. The pixel 220 may additionally include a thin film transistor depending on a driving manner, and the thin film transistor may be electrically connected to the first electrode.

A protective layer 230 is positioned on the pixel 220 to cover the pixel 220. An organic phosphor layer 240 may be positioned on the protective layer 230 at a location corresponding to the pixel 220. The organic phosphor layer 240 may be formed of a low molecular weight organic material and a high molecular weight organic material.

In case that the organic phosphor layer 240 is formed of a low molecular weight organic material, the organic phosphor layer 240 may be formed using a thermal evaporation method. In case that the organic phosphor layer 240 is formed of a high molecular weight organic material, the organic phosphor layer 240 may be formed using a spin coating method.

The organic phosphor layer 240 may include any one selected from the group consisting of anthracene-based compound, pyrene-based compound, perylene-based compound, and coumarin-based compound.

Light produced by the organic phosphor layer 240 may be represented by X and Y coordinates based on CIE color system. The X coordinate may lie substantially in a range between 0.300 and 0.700, and the Y coordinate may lie substantially in a range between 0.200 and 0.600. The organic phosphor layer 240 may substantially have a thickness of 0.1 μm to 100 μm so as to efficiently perform a color change operation.

A protective unit 250 may be attached to the first substrate 210, on which the pixel 220 is positioned, using a sealant (S). The protective unit 250 may be a glass or a cap having light transmission properties depending on light emitting characteristics of the light emitting device 200.

In the light emitting device 200, the light emitting layer of the pixel 220 may produce blue-based light, and the organic phosphor layer 240 may produce yellow-based light or orange-based light. Hence, the blue-based light produced by the pixel 220 passes through the organic phosphor layer 240 and then is incident on the protective unit 250, and thus can be changed into white-based light.

Further, in the light emitting device 200, the light emitting layer of the pixel 220 may produce blue-based light. Although it is not shown, the organic phosphor layer 240 may include a first organic phosphor layer emitting red-based light and a second organic phosphor layer emitting green-based light. Hence, the blue-based light produced by the pixel 220 passes through the organic phosphor layer 240 and then is incident on the protective unit 250, and thus can be changed into white-based light.

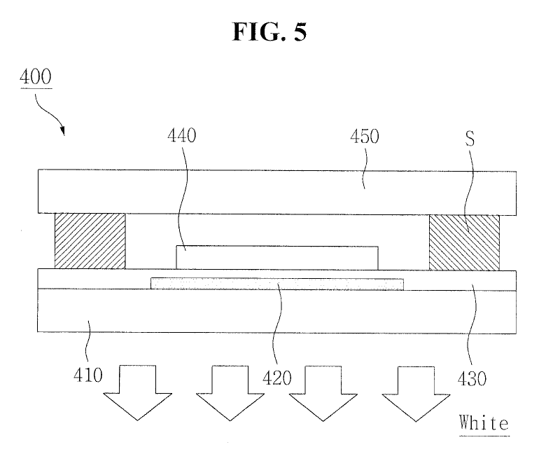

FIG. 4 is a cross-sectional view showing a third implementation of a structure of the light emitting device according to the exemplary embodiment.

As shown in FIG. 4, a light emitting device 300 includes a first substrate 310 and a pixel 320 on the first substrate 310. The pixel 320 may include a light emitting layer. The pixel 320 may additionally include a thin film transistor depending on a driving manner, and the thin film transistor may be electrically connected to an anode electrode.

A protective layer 340 having a multi-layered structure and an organic phosphor layer 350 are positioned on the pixel 320 to cover the pixel 320. For instance, the protective layer 340 may include first and second protective layers 340a and 340b.

More specifically, the first protective layer 340a covering the pixel 320 is positioned on the first substrate 310. The organic phosphor layer 350 may be positioned on the first protective layer 340a at a location corresponding to the pixel 320. The organic phosphor layer 350 may be formed of a low molecular weight organic material and a high molecular weight organic material. The second protective layer 340b is positioned on the organic phosphor layer 350. The first protective layer 340a or the second protective layer 340b can protect the pixel 320 from the outside air. The first and second protective layers 340a and 340b may be formed of the same material, and thus the continuity of an evaporation process can be maintained. Hence, process time and manufacturing cost can be reduced.

The protective layer 340 may be formed of an inorganic material having light transmission properties depending on light emitting characteristics of the light emitting device 300.

The organic phosphor layer 350 may include any one selected from the group consisting of anthracene-based compound, pyrene-based compound, perlyene-based compound, and coumarin-based compound.

Light produced by the organic phosphor layer 350 may be represented by X and Y coordinates based on CIE color system. The X coordinate may lie substantially in a range between 0.300 and 0.700, and the Y coordinate may lie substantially in a range between 0.200 and 0.600. The organic phosphor layer 350 may substantially have a thickness of 0.1 μm to 100 μm so as to efficiently perform a color change operation.

In the light emitting device 300, the light emitting layer of the pixel 320 may produce blue-based light, and the organic phosphor layer 350 may produce yellow-based light or orange-based light. Hence, the blue-based light produced by the pixel 320 passes through the organic phosphor layer 350 and then is incident on the protective layer 340, and thus can be changed into white-based light.

Further, in the light emitting device 300, the light emitting layer of the pixel 320 may produce blue-based light. Although it is not shown, the organic phosphor layer 350 may include a first organic phosphor layer emitting red-based light and a second organic phosphor layer emitting green-based light. Hence, the blue-based light produced by the pixel 320 passes through the organic phosphor layer 350 and then is incident on the protective layer 340, and thus can be changed into white-based light.

FIG. 5 is a cross-sectional view showing a fourth implementation of a structure of the light emitting device according to the exemplary embodiment.

As shown in FIG. 5, a light emitting device 400 includes a first substrate 410 and an organic phosphor layer 420 positioned at a location corresponding to a light emitting area on the first substrate 410. The organic phosphor layer 420 may be formed of a low molecular weight organic material and a high molecular weight organic material.

An insulating layer 430 may be positioned on the organic phosphor layer 420 to cover the organic phosphor layer 420 and to improve the insulation and the surface roughness of the first substrate 410. The insulating layer 430 may be formed of SiO-based organic/inorganic mixture layer or an inorganic layer including one selected from the group consisting of SiO₂, SiON, and SiN.

A pixel 440 may be positioned on the insulating layer 430. The pixel 440 may include a light emitting layer interposed between a first electrode and a second electrode. The pixel 440 may additionally include a thin film transistor depending on a driving manner, and the thin film transistor may be electrically connected to the first electrode.

A protective unit 450 may be on the pixel 440 to protect the pixel 440 from the outside air. The protective unit 450 may be attached to the first substrate 410 using a sealant (S). The protective unit 450 may be a glass or a cap having a predetermined reflectance depending on light emitting characteristics of the light emitting device 400.

The organic phosphor layer 420 may include any one selected from the group consisting of anthracene-based compound, pyrene-based compound, perylene-based compound, and coumarin-based compound.

Light produced by the organic phosphor layer 420 may be represented by X and Y coordinates based on CIE color system. The X coordinate may lie substantially in a range between 0.300 and 0.700, and the Y coordinate may lie substantially in a range between 0.200 and 0.600. The organic phosphor layer 420 may substantially have a thickness of 0.1 μm to 100 μm so as to efficiently perform a color change operation.

In the light emitting device 400, the light emitting layer of the pixel 440 may produce blue-based light, and the organic phosphor layer 420 may produce yellow-based light or orange-based light. Hence, the blue-based light produced by the pixel 440 passes through the organic phosphor layer 420 and then is incident on the first substrate 410, and thus can be changed into white-based light.

Further, in the light emitting device 400, the light emitting layer of the pixel 440 may produce blue-based light. Although it is not shown, the organic phosphor layer 420 may include a first organic phosphor layer emitting red-based light and a second organic phosphor layer emitting green-based light. Hence, the blue-based light produced by the pixel 440 passes through the organic phosphor layer 420 and then is incident on the first substrate 410, and thus can be changed into white-based light.

In the various implementations according to the exemplary embodiment, the blue-based light may be represented by X coordinate of 0.13 to 0.18 and Y coordinate of 0.08 to 0.25. The red-based light may be represented by X coordinate of 0.65 to 0.70 and Y coordinate of 0.34 to 0.40. The green-based light may be represented by X coordinate of 0.25 to 0.33 and Y coordinate of 0.63 to 0.70.

The white-based light may be represented by X and Y coordinates based on 0.31 and 0.34, and the Y coordinate may lie substantially in a range between 0.32 and 0.35.

Color coordinate of light produced by the light emitting device according to the exemplary embodiment can be adjusted by adjusting the thickness of the organic phosphor layer.

In the light emitting device according to the exemplary embodiment, the light emitting layer may be formed of one of a phosphorescence material and a fluorescence material, and the light emitting layer may include one of an organic material or an inorganic material.

As described above, the light emitting device according to the exemplary embodiment can produce white-based light applicable to a light source and a backlight unit.

The foregoing embodiments and advantages are merely exemplary and are not to be construed as limiting the present invention. The present teaching can be readily applied to other types of apparatuses. The description of the foregoing embodiments is intended to be illustrative, and not to limit the scope of the claims. Many alternatives, modifications, and variations will be apparent to those skilled in the art.

What is claimed is:

1. A light emitting device comprising:
a first substrate;
a light emitting unit on the first substrate, the light emitting unit including a first electrode, a light emitting layer, and a second electrode; and
an organic phosphor layer positioned at a location corresponding to the light emitting layer.

2. The light emitting device of claim 1, further comprising a protective unit on the light emitting unit.

3. The light emitting device of claim 2, wherein the protective unit is a second substrate.

4. The light emitting device of claim 3, wherein the second substrate includes glass.

5. The light emitting device of claim 3, wherein the organic phosphor layer is positioned on one side of the second substrate

6. The light emitting device of claim 2, wherein the protective unit includes a first protective layer covering the light emitting unit, and the organic phosphor layer is positioned on the first protective layer.

7. The light emitting device of claim 6, wherein the protective unit further includes a second protective layer covering the organic phosphor layer.

8. The light emitting device of claim 7, wherein the first protective layer and the second protective layer are formed of the same material.

9. The light emitting device of claim 1, wherein the light emitting layer includes a material emitting blue-based light.

10. The light emitting device of claim 1, wherein the light emitting layer includes a phosphorescence material.

11. The light emitting device of claim 1, wherein the organic phosphor layer includes a material emitting yellow-based light or orange-based light.

12. The light emitting device of claim 1, wherein the organic phosphor layer includes a first organic phosphor layer including a material emitting red-based light and a second organic phosphor layer including a material emitting green-based light.

13. The light emitting device of claim 1, wherein the organic phosphor layer includes any one selected from the group consisting of anthracene-based compound, pyrene-based compound, perylene-based compound, and coumarin-based compound.

14. The light emitting device of claim 1, wherein the organic phosphor layer substantially has a thickness of 0.1 μm to 100 μm.

15. A light emitting device comprising:
a first substrate;
an organic phosphor layer on the first substrate;
an insulating layer covering the organic phosphor layer; and
a light emitting unit positioned on the insulating layer at a location corresponding to the organic phosphor layer.

16. The light emitting device of claim 15, further comprising a protective unit on the light emitting unit.

17. The light emitting device of claim 16, wherein the protective unit is a second substrate, and the second substrate includes glass.

18. The light emitting device of claim 15, wherein the light emitting layer includes a material emitting blue-based light.

19. The light emitting device of claim 15, wherein the light emitting layer includes a phosphorescence material.

20. The light emitting device of claim 15, wherein the organic phosphor layer includes a material emitting yellow-based light or orange-based light.

21. The light emitting device of claim 15, wherein the organic phosphor layer includes a first organic phosphor layer including a material emitting red-based light and a second organic phosphor layer including a material emitting green-based light.

22. The light emitting device of claim 15, wherein the organic phosphor layer includes any one selected from the group consisting of anthracene-based compound, pyrene-based compound, perylene-based compound, and coumarin-based compound.

23. The light emitting device of claim 15, wherein the organic phosphor layer substantially has a thickness of 0.1 μm to 100 μm.
